(19) United States
(12) Patent Application Publication
(10) Pub. No.: US 2021/0366966 A1
(43) Pub. Date: Nov. 25, 2021

(54) Photosensitive Sensor, Preparation Method Thereof, and Electronic Device

(71) Applicant: BOE Technology Group Co., Ltd., Beijing (CN)

(72) Inventors: Shipei LI, Beijing (CN); Lizhen ZHANG, Beijing (CN); Sheng XU, Beijing (CN); Wei HE, Beijing (CN); Huili WU, Beijing (CN); Xuefei ZHAO, Beijing (CN); Fang HE, Beijing (CN); Yi ZHOU, Beijing (CN); Ying ZHAO, Beijing (CN); Wusheng LI, Beijing (CN); Qi YAO, Beijing (CN)

(21) Appl. No.: 17/200,930

(22) Filed: Mar. 15, 2021

(30) Foreign Application Priority Data
May 20, 2020 (CN) 202010431731.7

(51) Int. Cl. H01L 27/146

(52) U.S. Cl. CPC H01L 27/14623; H01L 27/14685; H01L 27/14636; H01L 27/14612

(57) ABSTRACT

A photosensitive sensor, a preparation method thereof, and an electronic device, wherein the photosensitive sensor includes a substrate, the substrate having a sensing area, a plurality of regularly arranged sensing units being provided in the sensing area, a shielding layer being provided on a side of the sensing units away from the substrate, the shielding layer covering the sensing area, a material of the shielding layer being a transparent conductive material, and the shielding layer being connected with a constant voltage signal terminal.

### CROSS-REFERENCE TO RELATED APPLICATION

The present application claims the priority of Chinese Patent Application No. 202010431731.7 filed to the CNIPA on May 20, 2020, the content of which is hereby incorporated by reference.

### TECHNICAL FIELD

Embodiments of the present disclosure relate to, but are not limited to, the field of display technology, in particular to a photosensitive sensor, a preparation method thereof, and an electronic device.

### BACKGROUND

With the development of science and technology, photosensitive sensors have a development trend of portability and wide application. Photosensitive sensors may be realized by combining thin film transistors with photosensitive elements. With the development trend of full screen, under-screen fingerprint identification technology utilizing optical sensors has attracted much attention.

### SUMMARY

The following is a summary of the subject matter described in detail herein. This summary is not intended to limit the protection scope of the claims.

In one aspect, an embodiment of the present disclosure provides a photosensitive sensor, including a substrate, the substrate having a sensing area, a plurality of regularly arranged sensing units being provided in the sensing area, a shielding layer being provided on a side of the sensing units away from the substrate, the shielding layer covering the sensing area, a material of the shielding layer being a transparent conductive material, and the shielding layer being connected with a constant voltage signal terminal.

In another aspect, an embodiment of the present disclosure provides a method for preparing a photosensitive sensor, including: forming a plurality of regularly arranged sensing units in a sensing area of a substrate; and forming a shielding layer covering the sensing area on a side of the sensing units away from the substrate, a material of the shielding layer being a transparent conductive material, and the shielding layer being connected with a constant voltage signal terminal.

In a further aspect, an embodiment of the present disclosure provides an electronic device, including the photosensitive sensor as described above.

Other aspects will become apparent upon reading and understanding accompanying drawings and the detailed description.

### BRIEF DESCRIPTION OF DRAWINGS

Accompanying drawings are used to provide an understanding of technical solutions of the present disclosure and form a part of the specification. Together with embodiments of the present disclosure, they are used to explain technical solutions of the present disclosure and do not constitute a limitation on the technical solutions of the present disclosure.

FIG. 1 is a schematic structural view of a photosensitive sensor according to at least one embodiment of the present disclosure.

FIG. 2 is a schematic plan view of a photosensitive sensor according to at least one embodiment of the present disclosure.

FIG. 3 is a schematic sectional view taken along an A-A′ direction in FIG. 2.

FIG. 4 is a schematic view after forming a pattern of a gate electrode of a thin film transistor according to at least one embodiment of the present disclosure.

FIG. 5 is a schematic sectional view taken along an A-A direction in FIG. 4.

FIG. 6 is a schematic view after forming a pattern of an active layer of a thin film transistor according to at least one embodiment of the present disclosure.

FIG. 7 is a schematic sectional view taken along an A-A direction in FIG. 6.

FIG. 8 is a schematic view after forming patterns of a source electrode and a drain electrode of a thin film transistor according to at least one embodiment of the present disclosure.

FIG. 9 is a schematic sectional view taken along an A-A′ direction in FIG. 8.

FIG. 10 is a schematic view after forming a pattern of a second electrode of a photosensitive element according to at least one embodiment of the present disclosure.

FIG. 11 is a schematic sectional view taken along an A-A′ direction in FIG. 10.

FIG. 12 is a schematic view after forming a pattern of a third electrode of a photosensitive element according to at least one embodiment of the present disclosure.

FIG. 13 is a schematic sectional view taken along an A-A′ direction in FIG. 12.

FIG. 14 is a schematic flow chart of a method for preparing a photosensitive sensor according to at least one embodiment of the present disclosure.

### DETAILED DESCRIPTION

Multiple embodiments are described in the present disclosure, but the description is exemplary rather than limiting, and for those of ordinary skills in the art, there may be more embodiments and implementation solutions within the scope of the embodiments described in the present disclosure. Although many possible combinations of features are shown in the drawings and discussed in the Detailed Description, many other combinations of the disclosed features are also possible. Unless specifically limited, any feature or element of any embodiment may be used in combination with or in place of any other feature or element of any other embodiment.

The present disclosure includes and contemplates combinations with features and elements known to those of ordinary skills in the art. Embodiments, features and elements already disclosed in the present disclosure may also be combined with any conventional features or elements to form a unique solution defined by the claims. Any feature or element of any embodiment may also be combined with features or elements from other solutions to form another unique solution defined by the claims. Therefore, it should be understood that any of the features shown and discussed in the present disclosure may be implemented individually or in any suitable combination. Therefore, the embodiments are not otherwise limited except in accordance with the appended claims and equivalents thereof. In addition, one or more modifications and changes may be made within the protection scope of the appended claims.

Furthermore, in describing representative embodiments, the specification may have presented a method or process as a specific sequence of steps. However, to the extent that the method or process does not depend on the specific order of steps described herein, the method or process should not be limited to the specific order of steps described. As those of ordinary skills in the art will understand, other orders of steps are also possible. Therefore, the specific order of steps set forth in the specification should not be interpreted as limiting the claims. Furthermore, the claims for the method or process should not be limited to performing their steps in the written orders, and those skilled in the art can easily understand that these orders can be varied and still remain within the spirit and scope of the embodiments of the present disclosure.

In the drawings, the size of a constituent element, or the thickness or area of a layer, is sometimes exaggerated for clarity. Therefore, an embodiment of the present disclosure is not necessarily limited to the size, and the shape and dimension of each component in the drawings do not reflect real proportions. In addition, the drawings schematically show ideal examples, and an embodiment of the present disclosure is not limited to the shapes or values shown in the drawings.

Unless otherwise defined, technical terms or scientific terms used in the present disclosure have ordinary meanings understood by those of ordinary skills in the field to which the present disclosure pertains. The words “first”, “second” and the like used in the present disclosure do not indicate any order, quantity or importance, but are only used to distinguish different components. In the present disclosure, “plurality” may indicate the number of two or more. Similar words such as “including” or “containing” mean that elements or articles appearing before the word cover elements or articles listed after the word and their equivalents, without excluding other elements or articles.

In the present disclosure, similar terms such as “connect”, “couple” or “link” are not limited to physical or mechanical connections, but may include electrical connections, whether direct or indirect. “Electrical connection” includes a case where the constituent elements are connected together by an element having a certain electrical function. The “element having a certain electrical function” is not particularly limited as long as it can transmit and receive electrical signals between connected constituent elements. Examples of the “element having a certain electrical function” not only include electrodes and wirings, but also include switching elements such as transistors, resistors, inductors, capacitors, and other elements with one or more functions.

In the present disclosure, a transistor refers to an element including three terminals, namely a gate electrode, a drain electrode and a source electrode. The transistor has a channel area between the drain electrode (a drain electrode terminal, a drain area or a drain electrode) and the source electrode (a source electrode terminal, a source area or a source electrode), and current can flow through the drain electrode, the channel area and the source electrode. In the present disclosure, the channel area refers to an area through which current mainly flows.

In a case where transistors with opposite polarities are used or the direction of current changes during circuit operation, the functions of “source electrode” and “drain electrode” are sometimes interchanged. Therefore, in the present disclosure, “source electrode” and “drain electrode” may be interchanged. Exemplarily, thin film transistors used in the present disclosure may be low-temperature polysilicon thin film transistors or oxide thin film transistors. The thin film transistor may be a P-type transistor or an N-type transistor.

In the present disclosure, “parallel” refers to a state in which an angle formed by two straight lines is −10 degrees or more and 10 degrees or less, and thus includes a state in which the angle is −5 degrees or more and 5 degrees or less. In addition, “vertical” refers to a state in which an angle formed by two straight lines is 80 degrees or more and 100 degrees or less, and thus includes a state in which the angle is 85 degrees or more and 95 degrees or less.

In the present disclosure, “film” and “layer” can be interchanged. For example, “conductive layer” can sometimes be replaced by “conductive film”. Similarly, “insulating film” can sometimes be replaced by “insulating layer”.

In order to keep the following description of the embodiments of the present disclosure clear and concise, detailed descriptions of some known functions and known components are omitted from the present disclosure. The accompanying drawings of the embodiments of the present disclosure only refer to structures involved in the embodiments of the present disclosure, and as to other structures, reference may be made to general designs.

An electronic device utilizing the under-screen fingerprint identification technology may include: a display module, a collimating optical path module and a photosensitive sensor. The collimating optical path module may be located between the display module and the photosensitive sensor, and the collimating optical path module and the photosensitive sensor may be located on a side of a display surface away from the display module. The display module may include an array substrate provided with a plurality of Organic Light-Emitting Diode (OLED) devices and a driving circuit. Light emitted by the OLED devices is reflected by a finger and reaches the photosensitive sensor through the collimating optical path module. The photosensitive sensor may convert a detected optical signal into an electrical signal, and the electrical signal generated by the photosensitive sensor may be used to identify a fingerprint image of the touching finger, thus realizing fingerprint identification. Since the photosensitive sensor is located on a side away from the display surface of the display module, electromagnetic signals generated by the array substrate of the display module will increase the noise of the photosensitive sensor and reduce the signal-to-noise ratio of the photosensitive sensor.

The display module and the collimating optical path module are hardware modules. For example, the display module may be any component that can realize display function, such as an LCD (Liquid Crystal Display) display screen or an OLED (Organic Light-Emitting Diode) display screen. Also, for example, the collimating optical path module may be any component that can realize a collimating optical path, such as a collimating lens or a laser pen.

Embodiments of the present disclosure provide a photosensitive sensor, a preparation method thereof, and an electronic device, which can reduce the noise of the photosensitive sensor and improve the signal-to-noise ratio of the photosensitive sensor.

The photosensitive sensor provided by an embodiment of the present disclosure includes: a substrate, the substrate having a sensing area, a plurality of regularly arranged sensing units being provided in the sensing area, a shielding layer being provided on a side of the sensing units away from the substrate, the shielding layer covering the sensing area, a material of the shielding layer being a transparent conductive material, and the shielding layer being connected with a constant voltage signal terminal.

In some exemplary embodiments, the transparent conductive material used for the shielding layer may include indium tin oxide (ITO). However, this is not limited in the present embodiment. In some examples, the shielding layer may be made of other types of materials with relatively higher transmittance and conductivity.

In some exemplary embodiments, a thickness range of the shielding layer may be greater than or equal to 400 angstroms (Å) to ensure uniformity and continuity of the shielding layer. In some examples, the thickness of the shielding layer may be 400 angstroms. However, this is not limited in the present embodiment.

In some exemplary embodiments, a constant voltage provided by the constant voltage signal terminal may range from −4 to 4 volts (V). In some examples, the constant voltage signal terminal may provide a fixed voltage signal with a voltage value of −1V. However, this is not limited in the present embodiment. Electromagnetic shielding effect may be effectively realized by connecting the shielding layer to the constant voltage signal terminal, thus reducing the noise of the photosensitive sensor.

In some exemplary embodiments, the shielding layer may be grounded. In some examples, the substrate may also have a binding area provided with a plurality of binding electrodes. The shielding layer may be connected with a binding electrode (i.e., a constant voltage signal terminal) in the binding area that is connected with ground signals, and the shielding layer may receive ground signals through the binding electrode. By grounding the shielding layer, electromagnetic shielding may be effectively realized and the noise of the photosensitive sensor may be reduced. However, this is not limited in the present embodiment. In some examples, the constant voltage signal terminal may be other electrodes that provide a fixed-value voltage.

According to the photosensitive sensor provided by an embodiment of the present disclosure, by covering the sensing area with the shielding layer, external electromagnetic waves will be continuously attenuated when penetrating into the shielding layer until they are attenuated to zero, thereby effectively shielding external electromagnetic interference to the photosensitive sensor. As the photosensitive sensor is a light-receiving device, preparing the shielding layer with a transparent conductive material having good conductivity and magnetic permeability can not only ensure that the photosensitive sensor senses light effectively, but also ensure the electromagnetic shielding effect.

In some examples, the photosensitive sensor of an embodiment of the present disclosure may be applied to an electronic device utilizing an under-screen fingerprint identification technology, and the photosensitive sensor may be located on a side away from the display surface of the display module. In this way, the electromagnetic interference from the display module can be effectively shielded by the shielding layer, thereby reducing the noise of the photosensitive sensor and improving the signal-to-noise ratio of the photosensitive sensor. However, this is not limited in the present embodiment. In some examples, the photosensitive sensor of an embodiment of the present disclosure may be applied to scenarios such as face identification or X-ray identification.

In some exemplary embodiments, the sensing unit may include a thin film transistor and a photosensitive element. The photosensitive element may include: a first electrode connected with a source electrode or a drain electrode of the thin film transistor, a photosensitive layer formed on the first electrode, a second electrode formed on the photosensitive layer, and a third electrode connected with the second electrode. Materials of the second electrode and the third electrode of the photosensitive element may be transparent conductive materials. An orthographic projection of the third electrode on the substrate may cover an orthographic projection of the photosensitive layer on the substrate.

In some examples, the photosensitive element may be a PIN (p-intrinsic-n) type photodiode. The photosensitive layer may include an N-type semiconductor layer, an intrinsic semiconductor layer and a P-type semiconductor layer stacked in a thickness direction of the substrate, wherein the N-type semiconductor layer may be disposed close to the first electrode of the photosensitive element.

In some examples, the second electrode and the third electrode of the photosensitive element may be made of a same transparent conductive material, for example, ITO. Since materials of the same type lead to higher matching degree and lower noise, a dark current of the photosensitive element may be reduced, thereby improving the sensitivity of the photosensitive element. However, this is not limited in the present embodiment. In some examples, the second electrode and the third electrode of the photosensitive element may be made of different transparent conductive materials.

In some examples, the thickness of the third electrode may be 700 angstroms. However, this is not limited in the present embodiment.

In some exemplary embodiments, the third electrodes of a plurality of photosensitive elements may be of an integrated structure in which they are connected with each other, and they may be configured to provide a working voltage to second electrodes of the photosensitive elements. In some examples, the third electrode of the photosensitive element may provide the second electrode with a negative bias voltage required by the operation of the photosensitive element, so that when photons with sufficient energy are incident on the photosensitive layer of the photosensitive element, the photosensitive layer may be excited to generate photo-generated charges, thereby forming electrical signals.

In some exemplary embodiments, the thin film transistor of the sensing unit may include a gate electrode located on the substrate, a first insulating layer covering the gate electrode, an active layer formed on the first insulating layer, and a source electrode and a drain electrode arranged on the same layer. The source electrode and the drain electrode are connected with the active layer. The first electrode of the photosensitive element may be arranged on the same layer as the source electrode and the drain electrode of the thin film transistor, and the first electrode of the photosensitive element and the source electrode or the drain electrode of the thin film transistor may be of an integrated structure. In some examples, the first electrode of the photosensitive element may be formed synchronously with the source electrode and the drain electrode of the thin film transistor through one patterning process. However, this is not limited in the present embodiment. In some examples, the first electrode of the photosensitive element may be formed after the formation of the source electrode and the drain electrode of the thin film transistor.

In some exemplary embodiments, the photosensitive sensor may further include: a plurality of parallel sensing control lines and a plurality of parallel signal reading lines. The sensing units may be disposed in sub-areas formed by intersection of the sensing control lines and the signal reading lines. The gate electrode of the thin film transistor of the sensing unit is connected with a corresponding sensing control line, and the source electrode or the drain electrode of the thin film transistor is connected with a corresponding signal reading line. An orthographic projection of the third electrodes of the plurality of photosensitive elements on the substrate may partially overlap with an orthographic projection of the sensing control lines on the substrate and partially overlap with an orthographic projection of the signal reading lines on the substrate. In some examples, with the connection being ensured, the third electrodes of a plurality of photosensitive elements may be designed to have openings directly above the sensing control lines and the signal reading lines (i.e., the orthographic projection of the third electrodes of the plurality of photosensitive elements on the substrate does not cover all the sensing control lines and signal reading lines), which can effectively reduce parasitic capacitance generated between the third electrodes and the sensing control lines and signal reading lines. Therefore, it is beneficial to reducing the noise of the photosensitive sensor and improving the signal-to-noise ratio of the photosensitive sensor.

In some exemplary embodiments, the sensing control lines may be arranged on the same layer as the gate electrodes of the thin film transistors, and the sensing control lines and the gate electrodes of the plurality of thin film transistors connected correspondingly thereto may be of an integrated structure. The signal reading lines may be arranged on the same layer as the source electrodes and the drain electrodes of the thin film transistors, and the signal reading lines and the source electrodes or the drain electrodes of the plurality of thin film transistors correspondingly connected thereto may be of an integrated structure. In some examples, the sensing control lines may be formed synchronously with the gate electrodes of the thin film transistors through one patterning process, and the signal reading lines may be formed synchronously with the source electrodes and the drain electrodes of the thin film transistors through one patterning process, thereby reducing the preparation procedures of the photosensitive sensor.

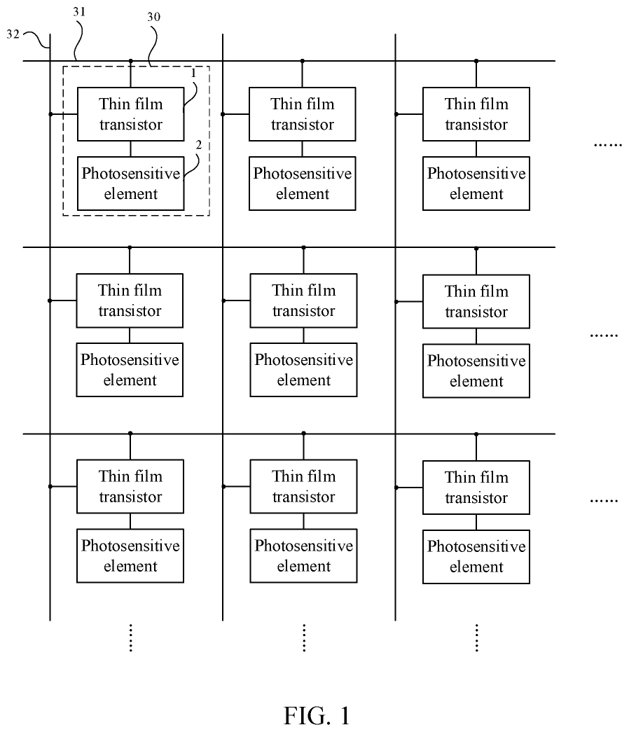

FIG. 1 is a schematic structural view of a photosensitive sensor according to at least one embodiment of the present disclosure. The photosensitive sensor provided by this exemplary embodiment may include a substrate. The substrate may have a sensing area in which a plurality of sensing control lines 31 arranged in parallel, a plurality of signal reading lines 32 arranged in parallel and a plurality of sensing units 30 arranged regularly are arranged. The plurality of sensing control lines 31 and the plurality of signal reading lines 32 intersect to form a plurality of sub-areas, and each sub-area is provided with a sensing unit 30. In some examples, the plurality of sensing control lines 31 may be arranged in the column direction, with the sensing control lines 31 being parallel to the horizontal direction; and the plurality of signal reading lines 32 may be arranged in the row direction, with the signal reading lines 32 being perpendicular to the horizontal direction. However, this is not limited in the present embodiment.

As shown in FIG. 1, the sensing unit 30 may include a thin film transistor 1 and a photosensitive element 2. The photosensitive element 2 may be connected with the thin film transistor 1, and the thin film transistor 1 is connected with corresponding sensing control line 31 and signal reading line 32. In some examples, the gate electrode of the thin film transistor 1 may be connected with a corresponding sensing control line 31, the drain electrode of the thin film transistor 1 may be connected with a signal reading line 32, and the source electrode of the thin film transistor 1 may be connected with the photosensitive element 2. However, this is not limited in the present embodiment. In some examples, the source electrode and the drain electrode of the thin film transistor 1 may be interchanged in position.

As shown in FIG. 1, the photosensitive element 2 may sense optical signals to generate corresponding electrical signals, and the sensing control lines 31 may provide sensing control signals to the thin film transistor 1 connected thereto, so that the photosensitive element 2 outputs the generated electrical signals to the corresponding signal reading line 32.

In this exemplary embodiment, during the operation of the photosensitive element 2, the thin film transistor 1 may be in an off state under the control of the sensing control signal provided by the sensing control line 31, and charges generated by the photosensitive element 2 upon exposure to light may be accumulated in the active layer of the thin film transistor 1. When the thin film transistor 1 is turned on under the control of the sensing control signal provided by the sensing control line 31, the electrical signal generated by the photosensitive element 2 may flow into the corresponding signal reading line 32 through the thin film transistor 1, and the electrical signal is transmitted to a processing circuit by the signal reading line 32, for example, the processing circuit may perform fingerprint identification according to the received electrical signal.

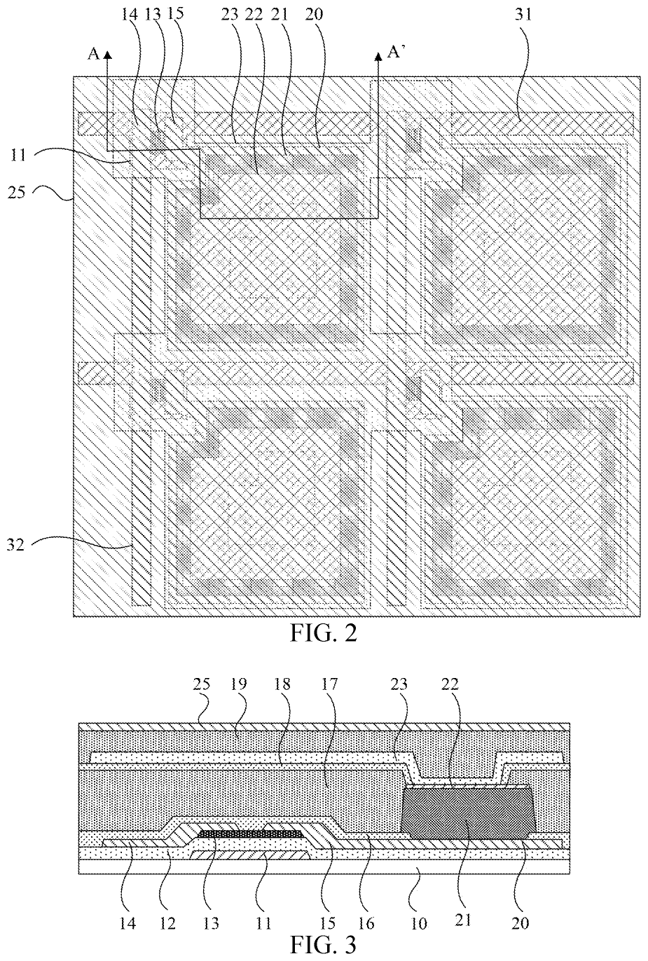

FIG. 2 is a schematic plan view of a photosensitive sensor according to at least one embodiment of the present disclosure. FIG. 3 is a schematic sectional view taken along an A-A′ direction in FIG. 2. As shown in FIG. 2 and FIG. 3, the thin film transistors and the photosensitive elements are located in the sub-areas formed by intersection of the sensing control lines 31 and the signal reading lines 32. The thin film transistors and the photosensitive elements may be disposed adjacent to each other on the substrate 10. However, this is not limited in the present embodiment. In some examples, the photosensitive elements and the thin film transistors may be stacked on the substrate, for example, the photosensitive elements may be located on the thin film transistors.

As shown in FIG. 3, in a plane perpendicular to the substrate 10, the thin film transistor may include: a gate electrode 11 on the substrate 10, a first insulating layer 12 covering the gate electrode 11, an active layer 13 formed on the first insulating layer 12, a source electrode 14 and a drain electrode 15 arranged on the same layer, and a second insulating layer 16 covering the active layer 13, the first insulating layer 12, the source electrode 14 and the drain electrode 15.

As shown in FIG. 3, in a plane perpendicular to the substrate 10, the photosensitive element may include: a first electrode 20 disposed on the same layer as the source electrode 14 and the drain electrode 15 of the thin film transistor, a photosensitive layer 21 formed on the first electrode 20, a second electrode 22 formed on the photosensitive layer 21, a flat layer 17, a third insulating layer 18, and a third electrode 23 connected with the second electrode 22.

In some exemplary embodiments, the first electrode 20 may be arranged on the same layer as the source electrode 14 and the drain electrode 15 of the thin film transistor, and the first electrode 20 and the drain electrode 15 may be of an integrated structure. The photosensitive layer 21 may be connected with the first electrode 20 through a first opening on the second insulating layer 16. The flat layer 17 and the third insulating layer 18 cover the second insulating layer 16, the first electrode 20, the photosensitive layer 21 and the second electrode 22. The third electrode 23 may be connected with the second electrode 22 through a second opening on the third insulating layer 18.

In some exemplary embodiments, as shown in FIG. 2 and FIG. 3, the orthographic projection of the third electrode 23 of the photosensitive element on the substrate 10 may cover the orthographic projection of the photosensitive layer 21 on the substrate 10. The orthographic projection of the first electrode 20 on the substrate 10 may cover the orthographic projection of the photosensitive layer 21 on the substrate 10. The orthographic projection of the photosensitive layer 21 on the substrate 10 may cover the orthographic projection of the second electrode 22 on the substrate 10. The area of the second electrode 22 of the photosensitive element may be smaller than that of the photosensitive layer 21, thereby reducing the leakage current at the edge of the photosensitive element and further improving the sensitivity of the photosensitive element.

In some exemplary embodiments, as shown in FIG. 2 and FIG. 3, the third electrodes 23 of a plurality of photosensitive elements are connected with each other to form an integrated structure, and may provide a working voltage to the second electrodes 22 of the photosensitive elements. In some examples, the third electrode 23 may be used as a working voltage input end of the photosensitive sensor, which may realize overlap with the second electrode 22. As shown in FIG. 2, the orthographic projection of the third electrodes 23 of the plurality of photosensitive elements on the substrate 10 may partially overlap with the orthographic projection of the sensing control lines 31 on the substrate 10 and partially overlap with the orthographic projection of the signal reading lines 32 on the substrate 10, so as to effectively reduce parasitic capacitance generated between the third electrodes 23 and the sensing control lines 31 and the signal reading lines 32.

In some exemplary embodiments, as shown in FIG. 2 and FIG. 3, a shielding layer 25 may be provided on a side of the photosensitive element away from the substrate 10, and the shielding layer 25 may cover the sensing area. The material of the shielding layer 25 may be a transparent conductive material, such as ITO. The shielding layer 25 may be connected with a binding electrode in the binding area to realize grounding. However, this is not limited in the present embodiment.

According to the photosensitive sensor provided by an embodiment of the present disclosure, by providing a shielding layer covering the sensing area, it is possible to effectively shield electromagnetic interference from the outside, thereby reducing the noise of the photosensitive sensor and improving the signal-to-noise ratio of the photosensitive sensor.

A technical solution of an embodiment of the present disclosure is further described below by an example of a process for preparing a photosensitive sensor of the present exemplary embodiment. The “patterning process” mentioned in an embodiment of the present disclosure includes the treatments, such as film layer deposition, photoresist coating, mask exposure, development, etching, and photoresist stripping. Deposition may be implemented by using a process, such as sputtering, evaporation or chemical vapor deposition, coating may be implemented by using a coating process, and etching may be implemented by using an etching method, which is not limited here. In the description of an embodiment of the present disclosure, “thin film” refers to a layer of thin film fabricated by a certain material on a substrate by deposition or other processes.

The preparation process of the photosensitive sensor provided by an embodiment of the present disclosure may include the following steps.

(1) A pattern of a gate electrode is formed on a substrate.

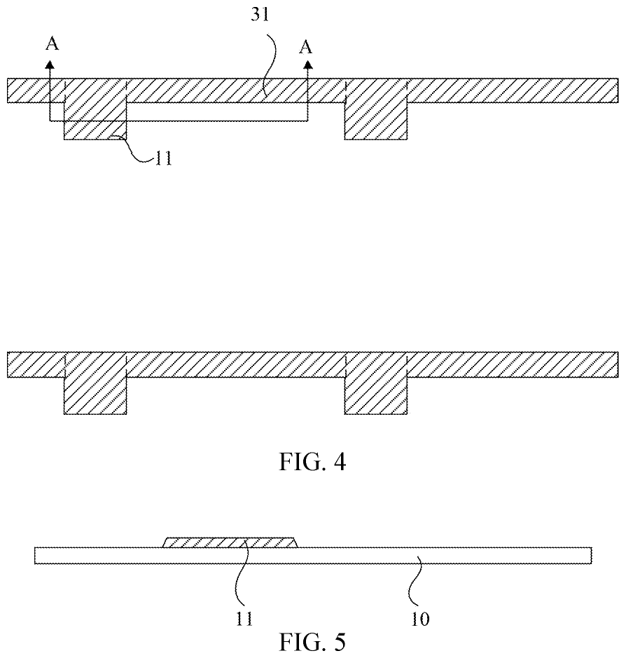

In some exemplary embodiments, forming a pattern of a gate electrode may include: depositing a first metal thin film on a substrate 10, and patterning the first metal thin film by a patterning process to form a pattern of a gate electrode 11 and a sensing control line 31 on the substrate 10. In some examples, as shown in FIG. 4 and FIG. 5, FIG. 5 is a sectional view taken along an A-A direction in FIG. 4, the gate electrode 11 of the thin film transistor is connected with the sensing control line 31. The gate electrodes 11 of the thin film transistors located in the same row may be of an integrated structure connected with the same sensing control line 31, and the sensing control line 31 may provide sensing control signals to the gate electrodes 11 to control the on-off of the thin film transistors. The sensing control line 31 may be parallel to the horizontal direction and arranged in the column direction. However, this is not limited in the present embodiment.

In some exemplary embodiments, the substrate 10 may be a rigid substrate, e.g., made of a material such as glass or quartz, or may be a flexible substrate, e.g., made of a material such as polyimide (PI), polyethylene terephthalate (PET) or a surface-treated polymer soft film.

In an exemplary embodiment, the first metal thin film may be made of a metal material, such as argentum (Ag), copper (Cu), aluminum (Al), molybdenum (Mo), or titanium (Ti), or an alloy material of the above metals, such as aluminum neodymium alloy (AlNd), or molybdenum niobium alloy (MoNb), and may be a multi-layer metal structure, such as Mo/Cu/Mo, or may be a stacked structure formed by a metal and a transparent conductive material, such as ITO/Ag/ITO.

(2) A pattern of an active layer is formed.

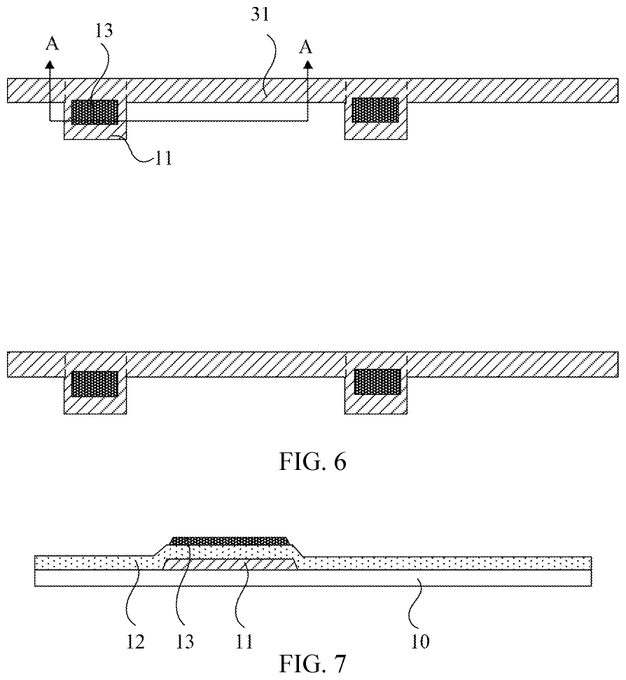

In some exemplary embodiments, forming a pattern of an active layer may include: sequentially depositing a first insulating thin film and an active thin film on the substrate 10 on which the aforementioned pattern is formed, wet etching the active thin film through a first photolithography process to form a pattern of an active layer 13, and then dry etching the first insulating thin film through a second photolithography process to form a pattern of a first insulating layer 12. In some examples, as shown in FIG. 6 and FIG. 7, FIG. 7 is schematic sectional view taken along an A-A direction in FIG. 6.

In some exemplary embodiments, the first insulating thin film may be made of silicon oxide (SiOx), silicon nitride (SiNx), silicon oxynitride (SiON), etc., or a high dielectric constant (High k) material such as aluminum oxide (AlOx), hafnium oxide (HfOx), tantalum oxide (TaOx), etc., and may be a single layer, multiple layers, or a composite layer. The first insulating layer may be referred to as a Gate Insulation (GI) layer.

In some exemplary embodiments, the active thin film may be made of any one or more of the following materials: an amorphous indium gallium zinc oxide (a-IGZO) material, an indium gallium zinc oxide (IGZO), indium zinc oxide (IZO), IGZXO, IGZYO, zinc oxynitride (ZnON), indium zinc tin oxide (IZTO), amorphous silicon (a-Si), polysilicon (p-Si), hexathiophene, polythiophene, etc. The present embodiment is applicable to a Top Gate Thin Film Transistor (TFT)-based display substrate manufactured through an oxide technology, a silicon technology or an organic technology.

(3) Patterns of a source electrode and a drain electrode are formed.

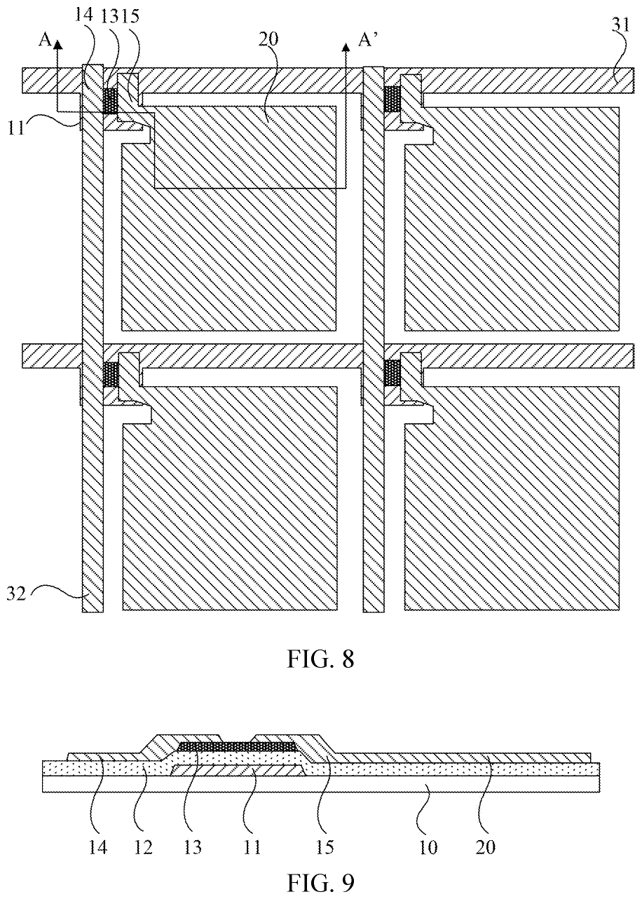

In some exemplary embodiments, forming patterns of a source electrode and a drain electrode may include: depositing a second metal thin film on the substrate 10 on which the aforementioned pattern is formed, and patterning the second metal thin film by a patterning process to form patterns of a source electrode 14 and a drain electrode 15, a signal reading line 32, and a first electrode 20 of the photosensitive element. In some examples, as shown in FIG. 8 and FIG. 9, FIG. 9 is a schematic sectional view taken along an A-A′ direction in FIG. 8, the source electrode 14 and the drain electrode 15 are connected with the two ends of the active layer 13, respectively. The source electrode 14 is connected with the signal reading line 32, and the source electrodes of the thin film transistors located in the same column may be of an integrated structure connected with the same signal reading line 32. The first electrode 20 of the photosensitive element and the drain electrode 15 of the thin film transistor may be of an integrated structure. However, this is not limited in the present embodiment. In some examples, the first electrode of the photosensitive element may be connected with the source electrode of the thin film transistor.

In some exemplary embodiments, the second metal thin film may be made of a metal material, such as argentum (Ag), copper (Cu), aluminum (Al), molybdenum (Mo), or titanium (Ti), or an alloy material of the above metals, such as aluminum neodymium alloy (AlNd), molybdenum niobium alloy (MoNb), and may be a multi-layer metal structure, such as Mo/Cu/Mo, or may be a stacked structure formed by a metal and a transparent conductive material, such as ITO/Ag/ITO.

(4) A pattern of a second insulating layer is formed.

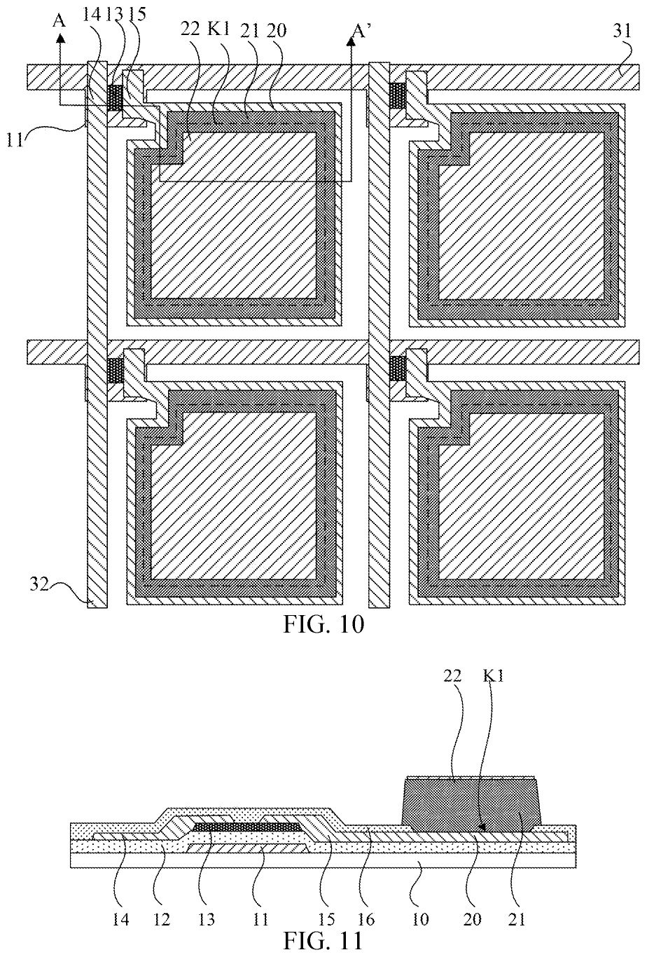

In some exemplary embodiments, forming a pattern of a second insulating layer may include: depositing a second insulating thin film on the substrate 10 on which the aforementioned patterns are formed, and dry etching the second insulating thin film by one photolithography process to form a pattern of a second insulating layer 16. In some examples, as shown in FIG. 10 and FIG. 11, FIG. 11 is a schematic sectional view taken along an A-A′ direction in FIG. 10, a first via K1 is formed on the second insulating layer 16, and the first via K1 may expose a surface of the first electrode 20.

In some exemplary embodiments, the second insulating thin film may be made of silicon oxide (SiOx), silicon nitride (SiNx), silicon oxynitride (SiON), etc., or a high dielectric constant (High k) material such as aluminum oxide (AlOx), hafnium oxide (HfOx), tantalum oxide (TaOx), etc., and may be a single layer, multiple layers, or a composite layer. The second insulating layer may be referred to as a first passivation layer (PVX).

A thin film transistor may be formed by steps (1) to (4).

In some exemplary embodiments, the gate electrode 11 of the thin film transistor and the sensing control line 31 may be arranged on the same layer, and the source electrode 14 and the drain electrode 15 of the thin film transistor, the signal reading line 32 and the first electrode 20 of the photosensitive element may be arranged on the same layer. The gate electrode 11 of the thin film transistor and the sensing control line 31 may be formed synchronously by one patterning process, and may be of an integrated structure. The source electrode 14 and the drain electrode 15 of the thin film transistor, the signal reading line 32 and the first electrode 20 of the photosensitive element may be synchronously formed by one patterning process. The source electrode 14 of the thin film transistor and the signal reading line 32 may be of an integrated structure, and the drain electrode 15 and the first electrode 20 of the photosensitive element may be of an integrated structure. This embodiment may simplify the preparation process of the photosensitive sensor.

(5) Patterns of a photosensitive layer and a second electrode are formed.

In some exemplary embodiments, forming patterns of a photosensitive layer and a second electrode pattern may include: sequentially depositing a photosensitive material and a first transparent conductive thin film on the substrate 10 on which the aforementioned pattern is formed, wet etching the first transparent conductive thin film by first photolithography, then dry etching the photosensitive material by a second photolithography process, e.g., RIE (Reactive Ion Etching) process, to form a pattern of a photosensitive layer 21, and then wet etching the first transparent conductive thin film after the first photolithography by a third photolithography process to form a pattern of a second electrode 22. In some examples, this is as shown in FIG. 10 and FIG. 11.

In some exemplary embodiments, as shown in FIG. 10, the orthographic projection of the first electrode 20 of the photosensitive element on the substrate 10 may cover the orthographic projection of the photosensitive layer 21 on the substrate 10. The orthographic projection of the photosensitive layer 21 on the substrate 10 may cover the orthographic projection of the second electrode 22 on the substrate 10. In this example, by etching the first transparent conductive thin film twice, it is possible to make the area of the second electrode 22 smaller than that of the photosensitive layer 21, thereby reducing the leakage current at the edge of the photosensitive element and further improving the sensitivity of the photosensitive element.

In some exemplary embodiments, the photosensitive material may include an organic photosensitive material. The first transparent conductive thin film may be made of a material such as indium tin oxide (ITO) or indium zinc oxide (IZO).

(6) Patterns of a flat layer and a third insulating layer are formed.

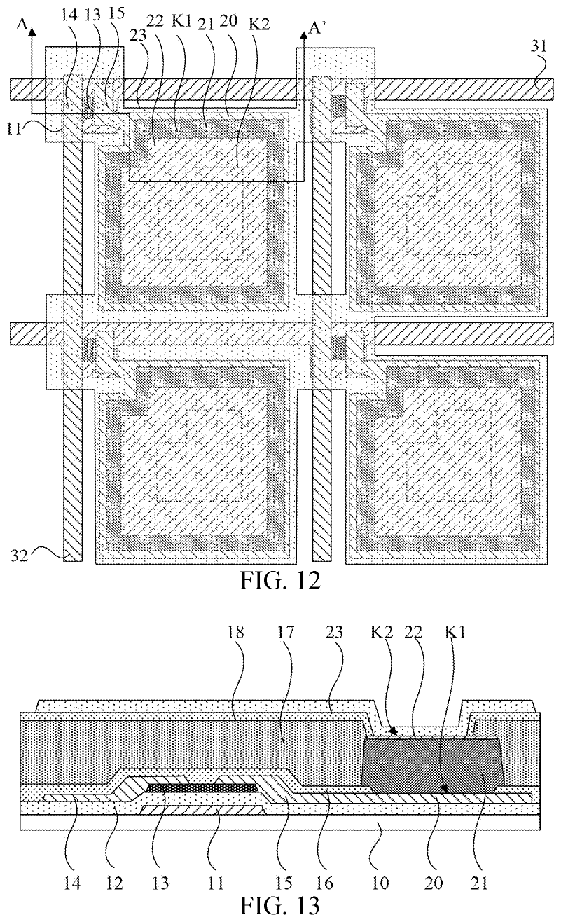

In some exemplary embodiments, forming patterns of a flat layer and a third insulating layer may include: coating a planarization thin film on the substrate 10 on which the aforementioned patterns are formed to form a pattern of a flat layer 17 through a photolithography process of masking, exposing and development, then depositing a third insulating thin film, and patterning the third insulating thin film by a patterning process to form a pattern of a third insulating layer 18. In some examples, as shown in FIG. 12 and FIG. 13, FIG. 13 is a schematic sectional view taken along an A-A′ direction in FIG. 12, a second via K2 is formed on the third insulating layer 18, and the flat layer 17 in the second via K2 is etched to expose a surface of the second electrode 22.

In some exemplary embodiments, a material of the planarization thin film may include, but is not limited to, polysiloxane-based materials, acrylic-based materials, polyimide-based materials, or the like.

In some exemplary embodiments, the third insulating thin film may be made of silicon oxide (SiOx), silicon nitride (SiNx), silicon oxynitride (SiON), etc., or a high dielectric constant (High k) material such as aluminum oxide (AlOx), hafnium oxide (HfOx), tantalum oxide (TaOx), etc., and may be a single layer, multiple layers, or a composite layer. The third insulating layer 18 may be referred to as a second passivation layer.

(7) A pattern of a third electrode is formed.

In some exemplary embodiments, forming a pattern of a third electrode may include: depositing a second transparent conductive thin film on the substrate 10 on which the aforementioned patterns are formed, and patterning the second transparent conductive thin film by a patterning process to form a pattern of a third electrode 23. In some examples, as shown in FIG. 12 and FIG. 13, the third electrode 23 may be connected with the second electrode 22 through the second via K2. The third electrode 23 may be a working voltage input end of the photosensitive element, and provides a working voltage to the second electrode 22.

In some exemplary embodiments, as shown in FIG. 12, the third electrodes 23 of a plurality of photosensitive elements may be of an integrated structure in which they are connected with each other. The orthographic projection of the integrated third electrodes 23 on the substrate 10 may cover the orthographic projection of the photosensitive layer 21 of the photosensitive element on the substrate 10, and may partially overlap with the orthographic projection of the sensing control line 31 on the substrate 10 and partially overlap with the orthographic projection of the signal reading line 32 on the substrate 10. In some examples, on the basis of ensuring that the third electrodes 23 of a plurality of photosensitive elements are connected with each other, the overlapping area with the sensing signal line 31 and the signal reading line 32 may be reduced, so that the parasitic capacitance between the third electrodes and the sensing signal line 31 and the signal reading line 32 may be reduced, and the noise of the photosensitive elements may be effectively reduced.

In some exemplary embodiments, the thickness of the third electrode 23 may be 700 angstroms. However, this is not limited in the present embodiment.

In some exemplary embodiments, the second transparent conductive thin film may be made of a material such as indium tin oxide (ITO) or indium zinc oxide (IZO).

In some exemplary embodiments, the materials of the second electrode 22 and the third electrode 23 of the photosensitive element may be the same type of materials, for example, both are ITO. Since materials of the same type lead to higher matching degree and lower noise, the dark current of the photosensitive element may be reduced, thereby improving the sensitivity of the photosensitive element.

In some exemplary embodiments, the third electrode 23 of the photosensitive element may be made of a transparent conductive material, and the orthographic projection of the third electrode 23 on the substrate 10 may cover the orthographic projection of the photosensitive layer 21 on the substrate 10, thereby increasing the effective photosensitive area of the photosensitive element and enhancing the quantity of optical signals received by the photosensitive element.

The photosensitive element may be formed by steps (4) to (7).

In some exemplary embodiments, the third electrodes 23 of a plurality of photosensitive elements may be of an integrated structure in which they are connected with each other. The third electrodes 23 of the plurality of photosensitive elements may be formed synchronously by one patterning process, which can simplify the preparation process of the photosensitive sensor.

(8) A pattern of a fourth insulating layer is formed.

In some exemplary embodiments, forming a pattern of a fourth insulating layer may include: depositing a fourth insulating thin film on the substrate 10 on which the aforementioned pattern is formed, and patterning the fourth insulating thin film by a patterning process to form a pattern of a fourth insulating layer 19. In some examples, as shown in FIG. 2 and FIG. 3, FIG. 3 is schematic sectional view taken along an A-A′ direction in FIG. 2.

In some exemplary embodiments, the fourth insulating thin film may be made of silicon oxide (SiOx), silicon nitride (SiNx), silicon oxynitride (SiON), etc., or a high dielectric constant (High k) material such as aluminum oxide (AlOx), hafnium oxide (HfOx), tantalum oxide (TaOx), etc., and may be a single layer, multiple layers, or a composite layer. The fourth insulating layer may be referred to as a third passivation layer (PVX).

(9) A pattern of a shielding layer is formed.

In some exemplary embodiments, forming a shielding layer may include: depositing a third transparent conductive thin film on the substrate 10 on which the aforementioned pattern is formed, and patterning the third transparent conductive thin film by a patterning process to form a pattern of a shielding layer 25. In some examples, as shown in FIG. 2 and FIG. 3, the shielding layer 25 may cover the sensing area where the thin film transistor and the photosensitive element are located. In some examples, the thickness of the shielding layer 25 may be 400 angstroms.

In some exemplary embodiments, the shielding layer 25 may be connected with a binding electrode in the binding area of the photosensitive sensor, and used for receiving ground signals and realizing grounding. However, this is not limited in the present embodiment.

In some exemplary embodiments, the third transparent conductive thin film may be made of a material such as indium tin oxide (ITO) or indium zinc oxide (IZO).

In some exemplary embodiments, the material of the shielding layer 25 may be the same as that of the third electrode 23, for example, both of them are ITO. However, this is not limited in the present embodiment.

In some exemplary embodiments, the photosensitive sensor provided by an embodiment of the present disclosure may be disposed on a side of a light emitting surface away from an OLED display module to support the realization of fingerprint identification. In the photosensitive sensor, the shielding layer is formed with a transparent conductive material with high transmittance and conductivity, which can effectively shield the electromagnetic interference of the OLED display module. Furthermore, the third electrode is formed with a transparent conductive material, which can effectively increase the effective light absorption area of the photosensitive element.

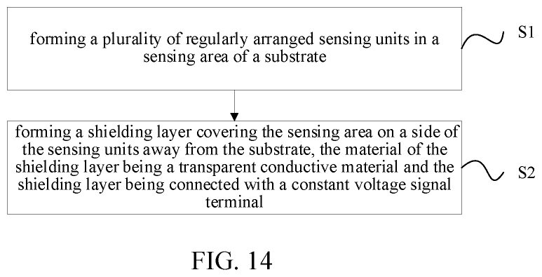

FIG. 14 is a method for preparing a photosensitive sensor according to at least one embodiment of the present disclosure. As shown in FIG. 14, the method for preparing a photosensitive sensor according to an embodiment of the present disclosure includes:

S1, forming a plurality of regularly arranged sensing units in a sensing area of a substrate; and

S2, forming a shielding layer covering the sensing area on a side of the sensing units away from the substrate, the material of the shielding layer being a transparent conductive material and the shielding layer being connected with a constant voltage signal terminal.

In some exemplary embodiments, forming a plurality of regularly arranged sensing units in a sensing area of a substrate may include: forming a thin film transistor on the substrate, wherein a source electrode and a drain electrode of the thin film transistor and a first electrode of a photosensitive element are synchronously formed, and the first electrode of the photosensitive element is connected with the source electrode or the drain electrode of the thin film transistor; forming a photosensitive layer of the photosensitive element on the first electrode of the photosensitive element; forming a second electrode of the photosensitive element on the photosensitive layer of the photosensitive element, wherein the material of the second electrode is a transparent conductive material; and forming a third electrode connected with the second electrode. The third electrode provides a working voltage to the second electrode of the photosensitive element, and the material of the third electrode may be a transparent conductive material. The orthographic projection of the third electrode of the photosensitive element on the substrate may cover the orthographic projection of the photosensitive layer of the photosensitive element on the substrate.

The preparation process of the photosensitive sensor has been described in detail in the previous embodiment and will not be repeated here.

An embodiment of the present disclosure further provides an electronic device, including the photosensitive sensor described above. The electronic device of an embodiment of the present disclosure may be any product or component with a light sensing function, such as a mobile phone, a tablet computer, a television, a display, a notebook computer, a digital photo frame, a navigator, etc.

In some exemplary embodiments, the electronic device may be a display apparatus with fingerprint identification function, and the electronic device may include a display module and a photosensitive sensor, and the photosensitive sensor may be located on a side of the light emitting surface away from the display module. For the electronic device provided by this exemplary embodiment, stability and reliability may be improved by using the photosensitive sensor of the foregoing embodiment.

In the description of the embodiments of the present disclosure, the orientation or position relationship indicated by the terms “middle”, “upper”, “lower”, “front”, “rear”, “vertical”, “horizontal”, “top”, “bottom”, “inner”, “outer” and the like is based on the orientation or position relationship shown in the drawings, which is only for the convenience of describing the present disclosure and simplifying the description, rather than indicating or implying that the apparatus or element referred to must have the specific orientation, or be constructed and operated in the specific orientation, and thus cannot be interpreted as a limitation on the present disclosure.

Although the embodiments disclosed in the present disclosure are as described above, the described contents are only the embodiments for facilitating understanding of the present disclosure, which are not intended to limit the present disclosure. A person skilled in the art to which the present disclosure pertains may make any modifications and variations in the form and details of implementation without departing from the spirit and scope of the present disclosure. Nevertheless, the scope of patent protection of the present disclosure shall still be determined by the scope defined by the appended claims.

What we claim is:

1. A photosensitive sensor, comprising:
a substrate, the substrate having a sensing area, a plurality of regularly arranged sensing units being provided in the sensing area, a shielding layer being provided on a side of the sensing units away from the substrate, the shielding layer covering the sensing area, a material of the shielding layer being a transparent conductive material, and the shielding layer being connected with a constant voltage signal terminal.

2. The photosensitive sensor according to claim 1, wherein the sensing unit comprises a thin film transistor and a photosensitive element; the photosensitive element comprises: a first electrode connected with a source electrode or a drain electrode of the thin film transistor, a photosensitive layer formed on the first electrode, a second electrode formed on the photosensitive layer, and a third electrode connected with the second electrode;
materials of the second electrode and the third electrode of the photosensitive element are transparent conductive materials;
an orthographic projection of the third electrode on the substrate covers an orthographic projection of the photosensitive layer on the substrate.

3. The photosensitive sensor according to claim 2, wherein third electrodes of a plurality of photosensitive elements are of an integrated structure in which they are connected with each other, and are configured to provide a working voltage to second electrodes of the photosensitive elements.

4. The photosensitive sensor according to claim 2, wherein the thin film transistor comprises: a gate electrode located on the substrate, a first insulating layer covering the gate electrode, an active layer formed on the first insulating layer, and a source electrode and a drain electrode arranged on the same layer; the source electrode and the drain electrode are connected with the active layer;
the first electrode of the photosensitive element is arranged on the same layer as the source electrode and the drain electrode of the thin film transistor, and the first electrode of the photosensitive element and the source electrode or the drain electrode of the thin film transistor are of an integrated structure.

5. The photosensitive sensor according to claim 4, wherein the photosensitive sensor further comprises: a plurality of parallel sensing control lines and a plurality of parallel signal reading lines, the sensing units are disposed in sub-areas formed by intersection of the sensing control lines and the signal reading lines, the gate electrode of the thin film transistor of the sensing unit is connected with a corresponding sensing control line, and the source electrode or the drain electrode of the thin film transistor is connected with a corresponding signal reading line;
an orthographic projection of the third electrodes of the plurality of photosensitive elements on the substrate partially overlaps with an orthographic projection of the sensing control lines on the substrate and partially overlaps with an orthographic projection of the signal reading lines on the substrate.

6. The photosensitive sensor according to claim 5, wherein the sensing control lines are arranged on the same layer as the gate electrodes of the thin film transistors, and the sensing control lines and the gate electrodes of the plurality of thin film transistors connected correspondingly thereto are of an integrated structure;
the signal reading lines are arranged on the same layer as the source electrodes and the drain electrodes of the thin film transistors, and the signal reading lines and the source electrodes or the drain electrodes of the plurality of thin film transistors correspondingly connected thereto are of an integrated structure.

7. The photosensitive sensor according to claim 2, wherein the thickness of the third electrode is 700 angstroms.

8. The photosensitive sensor according to claim 1, wherein the shielding layer is grounded.

9. The photosensitive sensor according to claim 1, wherein a thickness range of the shielding layer is greater than or equal to 400 angstroms.

10. The photosensitive sensor according to claim 2, wherein the third electrode is connected with the second electrode through a via.

11. The photosensitive sensor according to claim 2, wherein the area of the second electrode of the photosensitive element is smaller than that of the photosensitive layer.

12. The photosensitive sensor according to claim 2, wherein an orthographic projection of the first electrode on the substrate covers an orthographic projection of the photosensitive layer on the substrate, and the orthographic projection of the photosensitive layer on the substrate covers an orthographic projection of the second electrode on the substrate.

13. The photosensitive sensor according to claim 2, wherein the second electrode and the third electrode are made of the same type of materials.

14. The photosensitive sensor according to claim 2, wherein a material of the second electrode and the third electrode is indium tin oxide (ITO).

15. The photosensitive sensor according to claim 1, wherein the substrate has a binding area provided with a plurality of binding electrodes, and the shielding layer is connected with a binding electrode in the binding area.

16. The photosensitive sensor according to claim 1, wherein a material of the shielding layer is indium tin oxide (ITO) or indium zinc oxide (IZO).

17. A method for preparing a photosensitive sensor, comprising:
forming a plurality of regularly arranged sensing units in a sensing area of a substrate; and
forming a shielding layer covering the sensing area on a side of the sensing units away from the substrate, a material of the shielding layer being a transparent conductive material, and the shielding layer being connected with a constant voltage signal terminal.

18. The method according to claim 17, wherein the forming a plurality of regularly arranged sensing units in a sensing area of a substrate comprises:
forming a thin film transistor on the substrate, wherein a source electrode and a drain electrode of the thin film transistor and a first electrode of a photosensitive element are synchronously formed, and the first electrode of the photosensitive element is connected with the source electrode or the drain electrode of the thin film transistor;
forming a photosensitive layer of the photosensitive element on the first electrode of the photosensitive element;
forming a second electrode of the photosensitive element on the photosensitive layer of the photosensitive element, wherein the material of the second electrode is a transparent conductive material; and
forming a third electrode connected with the second electrode, wherein the third electrode provides a working voltage to the second electrode of the photosensitive element, the material of the third electrode is a transparent conductive material, and the orthographic projection of the third electrode of the photosensitive element on the substrate covers the orthographic projection of the photosensitive layer of the photosensitive element on the substrate.

19. An electronic device, comprising the photosensitive sensor according to claim 1.

20. The electronic device according to claim 19, further comprising: a display module and a collimating optical path module, the collimating optical path module being located between the display module and the photosensitive sensor, and the collimating optical path module and the photosensitive sensor being located on a side of a display surface away from the display module.
